(19) United States
(12) Patent Application Publication
(10) Pub. No.: US 2013/0300592 A1
(43) Pub. Date: Nov. 14, 2013

(54) Device, System and Method For Digital Pulse-Density Modulation

(71) Applicant: Kapik Inc., Toronto (CA)

(72) Inventor: William Martin Snelgrove, Toronto (CA)

(21) Appl. No.: 13/892,112

(22) Filed: May 10, 2013

Related U.S. Application Data
(60) Provisional application No. 61/645,119, filed on May 10, 2012.

(51) Int. Cl. H03M 3/00

(52) U.S. Cl. CPC H03M 3/30
USPC 341/143

(57) ABSTRACT

A novel pulse density modulator is disclosed which includes at least one sigma delta modulator operating at a clock rate selected to provide a pre-selected timing resolution for sampling an input signal. The sigma delta modulator employs a hysteresis element to reduce the average transition rate of the output signal of the sigma delta modulator to reduce switching losses. The novel pulse density modulator can provide at least a two or three level output, as desired.

### RELATED APPLICATIONS

The present application claims priority from U.S. provisional application 61/645,119, filed May 10, 2012 and the contents of this earlier application are incorporated herein, in their entirety, by reference.

### FIELD OF THE INVENTION

The present invention relates to a device, system and method for generating pulse-density modulated (PDM) outputs. More specifically, the present invention relates to a device, system and method for creating a PDM output with synchronous digital circuits to reduce the otherwise required switching activity.

### BACKGROUND OF THE INVENTION

It is often desirable to drive loads such as, by way of example only, loudspeakers, with high efficiency in order to reduce heat generation and energy consumption. Several classes of electronic amplifiers are known to do this by driving the load, often in combination with a reactive circuit, with electronic switches. So called “Class D” switching amplifiers (including “Class AD” and “Class BD”) do this, as do “Class G”, “Class H” and others.

These amplifiers use a modulator circuit to define the required switching sequence, which is then implemented by a power-switching stage. In most practical amplifier designs, there may also be other components, such as feedback and protection circuits. The modulator circuit takes as input a representation of the desired output signal and produces switching signals to create an output that approximates that input.

In older technologies the input signal was generally in analog form, but in modern systems the input is digital. Many modulators first convert the digital signal to analog form and then use a traditional analog modulator to produce the switching waveforms. This is undesirable because analog processing is subject to variability over manufacturing, time and environmental conditions and it is preferred to produce the modulated signal entirely digitally.

Sigma delta modulators (SDMs) are known, and can be used to produce switching sequences closely tracking a digital input over a given range of frequencies, e.g. the audio range. SDMs oversample, meaning that their clock rates are higher than required for Nyquist sampling: typical oversampling for high-precision modulation might be by a factor of sixty-four or one-hundred and twenty-eight.

For the purpose of modulation for switching amplifiers, sigma-delta modulators typically switch too often. For example, good-quality analog Class D amplifiers for audio frequencies typically switch at about 1 MHz, whereas a sigma-delta modulator for audio purposes would typically be clocked at 3 MHz to 6 MHz and have average switching rates at up to half of that.

It is undesirable to switch too often because each switching event dissipates energy and causes high-current pulses, so that frequent switching reduces efficiency and increases electromagnetic interference. Frequent switching also increases harmonic distortion, because transition times in practical output stages are modulated by load current and particularly severely modulated in the case of inductive loads such as are typically required for smoothing switching waveforms.

Analog modulators can achieve a given performance level with low switching rates because they have high (in principle infinite) resolution on the timing of switching edges, whereas synchronous digital circuits can switch only at clock edges; and if the clock rate is set high to get fine resolution, the known modulators also switch frequently.

It is desired to develop synchronous digital circuits modulating switching waveforms but having average switching rates substantially lower than their clock rates. It is also desirable that such modulators reduce the worst types of electromagnetic interference and are capable of adjustment to trade off accuracy and switching rate. It is also desirable to minimize distortion due to signal modulation of the amplifier output impedance.

### SUMMARY OF THE INVENTION

It is an object of the present invention to provide a novel device, system and method for generating pulse-density modulated (PDM) outputs with synchronous digital circuits which obviates, or mitigates, at least one disadvantage of the prior art.

According to a first aspect of the present invention, there is provided A hysteretic pulse-density modulator operating on an input signal to produce an output signal, comprising: at least one a sigma delta modulator operating at a clock rate selected to provide a predefined level of timing resolution for sampling the input signal, the sigma delta modulator including a hysteresis element operable to reduce the average transition rate of the output signal of the sigma delta modulator to reduce switching losses.

The present invention provides a novel pulse density modulator which includes at least one sigma delta modulator operating at a clock rate selected to provide a pre-selected timing resolution for sampling an input signal. The sigma delta modulator employs a hysteresis element to reduce the average transition rate of the output signal of the sigma delta modulator to reduce switching losses. The novel pulse density modulator can provide at least a two or three level output, as desired.

More specifically, the present invention relates to a system and method using clocked digital circuits for producing n-ary outputs closely tracking the spectrum of a digital input signal over a frequency band of interest, where the average output switching rate is substantially smaller than the clock rate.

### BRIEF DESCRIPTION OF THE DRAWINGS

Preferred embodiments of the present invention will now be described, by way of example only, with reference to the attached Figures, wherein:

FIG. 1 shows a schematic representation of a prior art Class AD pulse width modulator driving a resistive load through an LC network;

FIG. 2 shows a schematic representation of a prior art Class BD pulse width modulator driving an inductive load;

FIG. 3 shows an output power spectrum for the Class BD pulse width modulator of FIG. 2 running at a fixed frequency;

FIG. 4 shows a prior-art analog pulse-width modulator using hysteretic control;

FIG. 5 shows a prior-art sigma-delta converter used as a modulator for a Class AD amplifier;

FIG. 6 shows the internal structure of a second-order embodiment of a prior-art sigma-delta converter used as a pulse-density modulator for a Class AD amplifier;

FIG. 7 shows an output power spectrum for a prior-art second-order embodiment of a prior-art sigma-delta converter used as a pulse-density modulator;

FIG. 8 shows a two-level hysteretic pulse-density modulator in accordance with the present invention, which is suitable for digital implementation of a Class-AD amplifier;

FIG. 9 shows an output power spectrum for the two-level hysteretic pulse-density modulator of FIG. 8;

FIG. 10 shows a three-level hysteretic pulse-density modulator in accordance with the present invention, which is suitable for digital implementation of a Class BD amplifier; and

FIG. 11 shows an output power spectrum for the three-level hysteretic pulse-density modulator of FIG. 10.

### DETAILED DESCRIPTION OF THE INVENTION

Before describing the present invention, prior art configurations of pulse width modulators and pulse density modulators will be described to assist in better understanding the present invention.

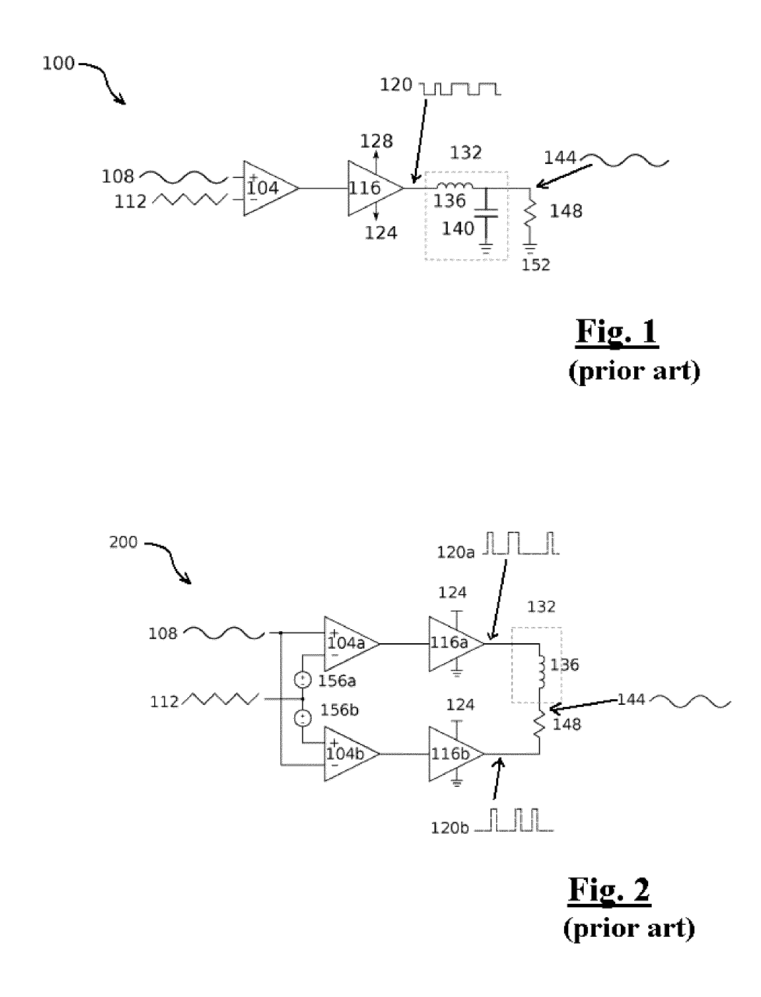

FIG. 1 shows generally at 100 a prior art pulse-width modulator comprising a comparator 104 which compares an input signal 108 to a reference triangle wave 112 and is operable to cause an output driver 116 to produce a switched waveform 120 that is substantially switched between negative power supply 124 and positive power supply 128. Waveform 120 is filtered by lowpass filter network 132 comprising series inductor 136 and, optionally, shunt capacitor 140, providing an output waveform 144 at load 148 terminated at ground 152. The intent is that produced output waveform 144 is similar to input signal 108 to an acceptable degree, for example having less than 0.1% distortion.

Those of skill in the art will recognize that many implementations of the architecture described in FIG. 1 are possible: for example the signals 108 and 112 may be represented as voltage or current analogies or as digital sequences; output driver 116 may be implemented differentially in a so-called “H-bridge” to remove the requirement for a negative power supply; lowpass filter network 132 may be augmented with an AC-coupling capacitor to remove the requirement for a negative power supply or may be replaced with any other network having an input impedance that is inductive at frequencies comparable to the frequency of reference triangle 112; etc. This inductive condition reduces energy loss in output driver 116 and is the key defining characteristic of a Class D amplifier and many of its variants. Circuits producing a switched output waveform 120 switching between exactly two levels are sometimes referred to as “Class AD” power amplifiers.

Circuits having the architecture of FIG. 1 are sometimes referred to as “pulse width modulators” (PWMs) because they produce a switched waveform 120 having a constant frequency (that of reference triangle wave 112) but whose width at any time is proportional to the level of input signal 108.

Those skilled in the art are also aware that the pulse-width modulator architecture described in FIG. 1 requires fine resolution in the widths of its pulses, and that a straightforward digital implementation may therefore require the use of high clock frequencies: for example, getting 0.1% resolution of pulse widths with a 1 MHz clock rate requires approximately a 1 GHz clock, which may be impractical. It is the synchronous character of clocked digital systems that causes this difficulty.

FIG. 2 shows generally at 200 a prior art Class BD pulse-width modulator comprising a pair of comparators 104a and 104b comparing an input signal 108 to a reference triangle wave 112 offset by a pair of fixed levels 156a and 156b and operable to cause a pair of output drivers 116a and 116b to produce a pair of switched waveforms 120a and 120b each substantially switched between positive power supply 124 and ground 156. The difference 160 between the voltages of waveforms 120a and 120b is a three-level switched waveform. This three-level switched waveform is filtered by lowpass filter network 132 comprising series inductor 136, providing an output waveform 144 across load 148 that is similar to input signal 108 to an acceptable degree, for example having less than 0.01% distortion.

Class BD amplifiers can be more efficient than Class AD amplifiers, particularly when the level of input signal 108 is small, but may produce more output distortion due to mismatches between impedances in drivers 116a and 116b and more electromagnetic interference due to excursions in the average (or “common mode”) of switching voltage waveforms 120a and 120b.

One skilled in the art will recognize the output configuration of drivers 116a and 116b as that of the “H bridge” referred to above, and will recognize that many implementations of the architecture of FIG. 2 are possible.

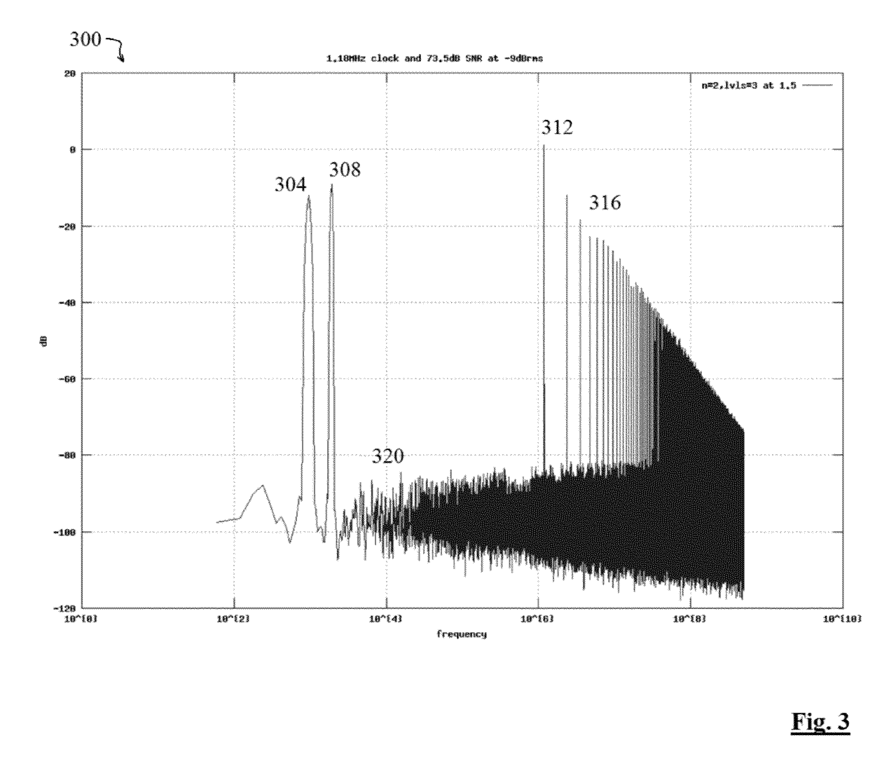

A digital implementation of the architecture of FIG. 2 generally suffers from the same requirement for fine timing resolution as does a digital (or any synchronous) implementation of FIG. 1. This is illustrated in FIG. 3, showing generally at 300 a power spectrum for the switching output of a digital simulated implementation of the architecture of FIG. 2, the implementation of this example being clocked at 1 GHz and with reference triangle wave 112 having a frequency of 1.18 MHz. The input signal applied is a sum of two sinusoidal tones, one at 1 kHz and a second at 2 kHz, each having peak voltage equal to one quarter of the peak voltage of triangle wave 112; these appear as “spikes” in a power spectrum, the input tone at 1 kHz corresponding to spike 304 and the input tone at 2 kHz corresponding to spike 308. Another large spike 312 appears at the frequency 1.18 MHz of the triangle wave 112, and may be expected to cause electromagnetic interference to any radio signals near this frequency. In particular, as 1.18 MHz is in the commercial AM radio band, this interference may cause nearby radios to be inoperable for certain stations, which in turn would make certification for sale of this implemented modulator very difficult. Indicated generally at 316 is a series of other spikes at odd harmonics 3, 5, 7 etc. times the 1.18 MHz tone, and each of these is another potential radio interferer.

Shown generally at 320 is a large collection of small spikes in the audio frequency band, typically defined as the band from about 20 Hz to about 20 kHz, caused by the inherent distortions of this style of modulator. While individual spikes are quite small, their net effect is large enough to make this implementation only marginally acceptable for audio use; in one standard subjective quality measure known as A-weighted signal to noise ratio, the quality of this modulator is calculated to be 73.5 dB when excited with the above-mentioned pair of tones; this is equivalent to approximately 0.03% distortion.

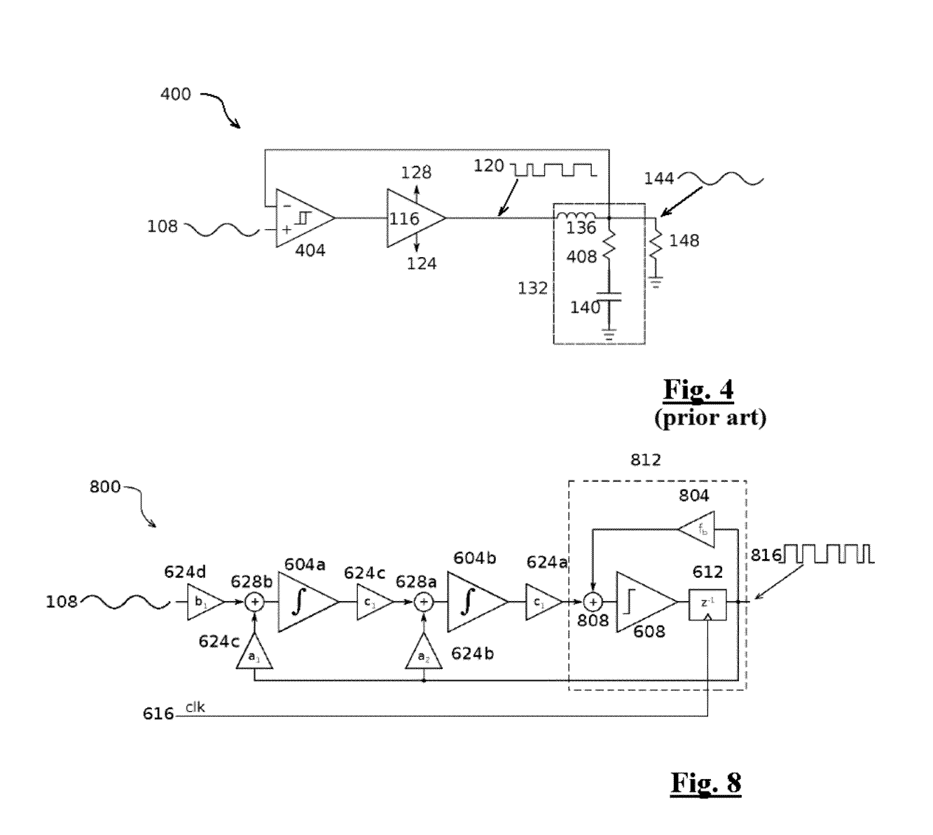

FIG. 4 shows generally at 400 a prior art self-oscillating hysteretic pulse density modulator comprising hysteretic comparator 404 comparing an input signal 108 to output signal 144 and operable to cause an output driver 116 to produce a switched waveform 120 that is substantially switched between negative power supply 124 and positive power supply 128. Waveform 120 is filtered by lowpass filter network 132 comprising series inductor 136, shunt capacitor 140, and effective series resistance 408 providing the output waveform 144 at load 148 terminated at ground 152 that is similar to the input signal 108 to an acceptable degree, for example having less than 0.1% distortion. For correct operation the feedback loop around comparator 404, driver 116 and filter network 132 is designed to self-oscillate using mathematical techniques which will be familiar to those skilled in the art.

The architecture of FIG. 4 is often described as a pulse density modulator rather than a pulse width modulator, because the feedback loop adjusts both oscillation frequency and pulse width in such a way as to produce a pulse stream whose density (also known as duty cycle, or probability of being “on”) is proportional to the input signal. Because of their use of feedback, these self-clocked pulse density modulators often provide better linearity (lower harmonic and intermodulation distortion) than the fixed-frequency modulators of FIGS. 1 and 2. Further, the switching behaviour of such PDMs is also often substantially random: while this makes them mathematically difficult to analyze, it reduces their tendency to produce output spikes which interfere with the electromagnetic spectrum.

One skilled in the art will recognize that a straightforward digital implementation of the architecture of FIG. 4 requires use of an analog-to-digital converter in the feedback loop because output signal 144 is necessarily in an analog form. The power consumption, complexity, and latency of such an analog-to-digital converter typically prevents this approach.

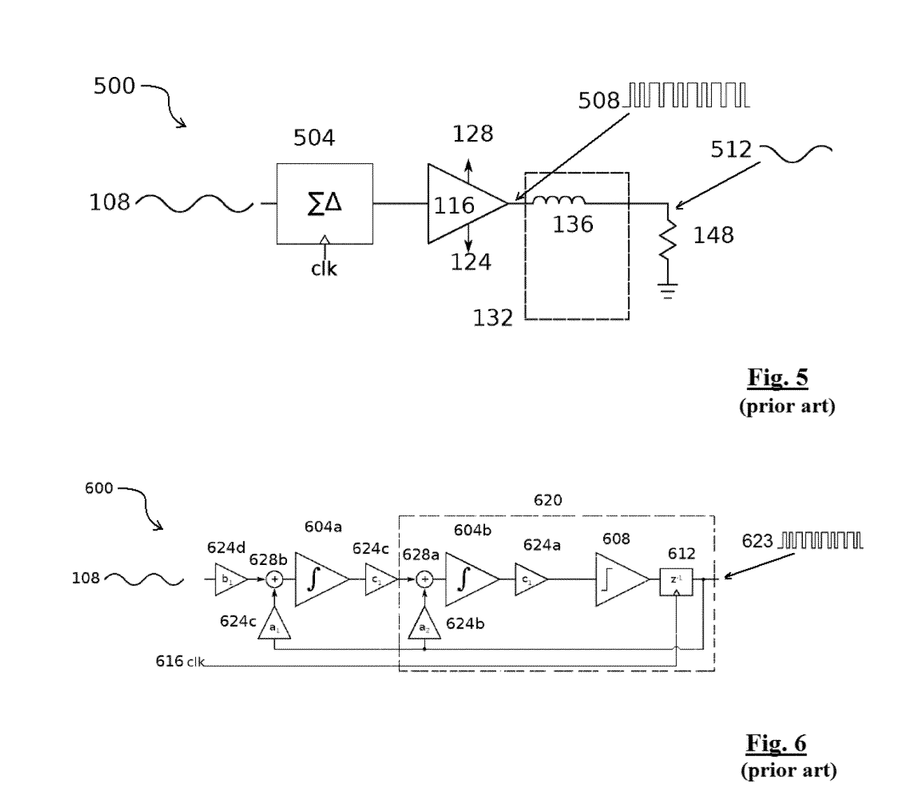

FIG. 5 shows generally at 500 a prior art sigma-delta pulse density modulator comprising a sigma-delta modulator 504 having an input signal 108 and clocked by clk. Sigma-delta modulator 504 is operable to cause output driver 116 to reproduce its output signal with a switching waveform 508 that is substantially switched between negative power supply 124 and positive power supply 128. Waveform 508 is filtered by lowpass filter network 132 comprising series inductor 136 and produces an output waveform 512, that is similar to input signal 108 to an acceptable degree, at load 148 which is terminated at ground 152. For example, waveform 512 may have less than 0.01% distortion relative to input 108.

Sigma-delta modulators are known to be capable of providing switching waveforms that very accurately represent their input signals over a desired range of frequencies, such as the range to which the human ear is sensitive, and are very amenable to digital implementation. It is known that they can also be designed to provide 3-level “Class BD” outputs if desired; and like the hysteretic modulators of FIG. 3 they tend to produce pseudo-random switching sequences that reduce the amount of electromagnetic interference that they produce. They thus have many of the properties—digital implementation, good EMI, and high linearity—that are desirable.

The difficulty with using sigma-delta modulators for Class D power amplifiers is that they create more switching events than do the analog implementations of FIGS. 1, 2 and 3. For example, switching rates of 3-5 MHz might be required to get the same accuracy that an analog implementation of the hysteretic pulse-density modulator of FIG. 3 could provide with average switching rates of only 1 MHz. This high rate of switching events reduces amplifier efficiency and increases electromagnetic interference. The problem is that a synchronous sigma-delta modulator running at 2 MHz can only place edges at 500 nsec increments, whereas the analog modulators of FIGS. 1 to 3 have in principle infinite timing resolution.

The prior art thus provides modulators well suited to analog implementation, as shown in FIGS. 1, 2 and 4, and having low switching rates and good efficiency; and modulators suitable for the more robust digital style of implementation, as shown in FIG. 5, but which have poor efficiency.

However, it is desired to have a modulator: suitable for digital implementation but with low average switching rates and therefore good efficiency; pseudo-random switching and therefore causing reduced electromagnetic interference; and, if possible, having means of correcting other known deficiencies such as the distortion caused by driver impedance mismatch in Class BD amplifiers. This desired modulator would ideally be configurable for both Class AD and Class BD modes of operation and configurable for a wide variety of performance levels in exchange for a range of efficiency levels. The use of digital implementation is known to make feature development more practical, and the desired modulator should be able to take advantage of this.

In the present invention, as described below, disadvantages of the prior art designs are overcome, at least in part, by adding hysteresis to the structure of a sigma-delta modulator. This novel design is unexpected as evidenced by the fact that the literature on sigma-delta modulation, in general, teaches against hysteresis as it reduces the accuracy of the output sequence at any given clock rate.

To make the invention clear we first present the internal architecture of a typical prior art sigma-delta modulator. FIG. 6 shows generally at 600 the architecture of a known implementation of a sigma-delta modulator having order two and a two-level output 623. Sigma-delta modulator 600 comprises two integrators 604a and 604b, quantizer 608, and register 612 clocked by clock signal 616, all interconnected in a pair of nested loops. Specifically, sigma-delta inner loop 620 comprises integrator 604b which is operable to control comparator 608 though gain coefficient 624a and comparator 608 is operable to set the state of register 612 at a rising edge of clock 616. Register 612 is operable to contribute to the input of integrator 604b through gain coefficient 624b and summer 628a.

Sigma-delta inner loop 620 in itself forms a sigma-delta modulator, said to be of order one, because it contains exactly one integrator. Sigma-delta modulator 600 can now be seen to comprise an outer loop comprising integrator 604a operable through gain coefficient 624c and summer 628a to control inner sigma-delta loop 620. Register 612 of sigma-delta inner loop 620 is operable through gain coefficient 624c and summer 628b to contribute to the input of integrator 604a. Input signal 108 also contributes to the input of integrator 604a through gain coefficient 624d and summer 628b, such that through this system of nested loops input signal 108 is operable to control output waveform 623. Sigma-delta modulator 600 is said to be of order two because it contains two integrators.

It is known to those skilled in the art that the mathematical properties of feedback systems dictate that the spectrum of output waveform 623 will closely approximate the spectrum of input signal 108 in a band of frequencies from zero, up to a small fraction—typically 1/64, of the frequency of input clock 616.

It is also known to design sigma-delta modulators with arbitrary orders and with two-state comparators generalized to quantizers having an arbitrary number of states, and in particular to quantizers having three output states.

It is also known to introduce additional loops which are operable to shape the power spectrum of error signals as appropriate for particular applications: for example, to make a modulator have its best performance at frequencies where the human ear is particularly sensitive.

It is also known to filter high-frequency components of output signals very conservatively and by way of compensation to pre-distort the input signal to a modulator so as to emphasize high frequencies.

It is further known to interconnect the integrators and quantizers in many different ways, and particular advantages and disadvantages are known for all of these choices. The particular architecture, order and quantizer accuracy shown in FIG. 6 must therefore be understood as being strictly illustrative and not limiting.

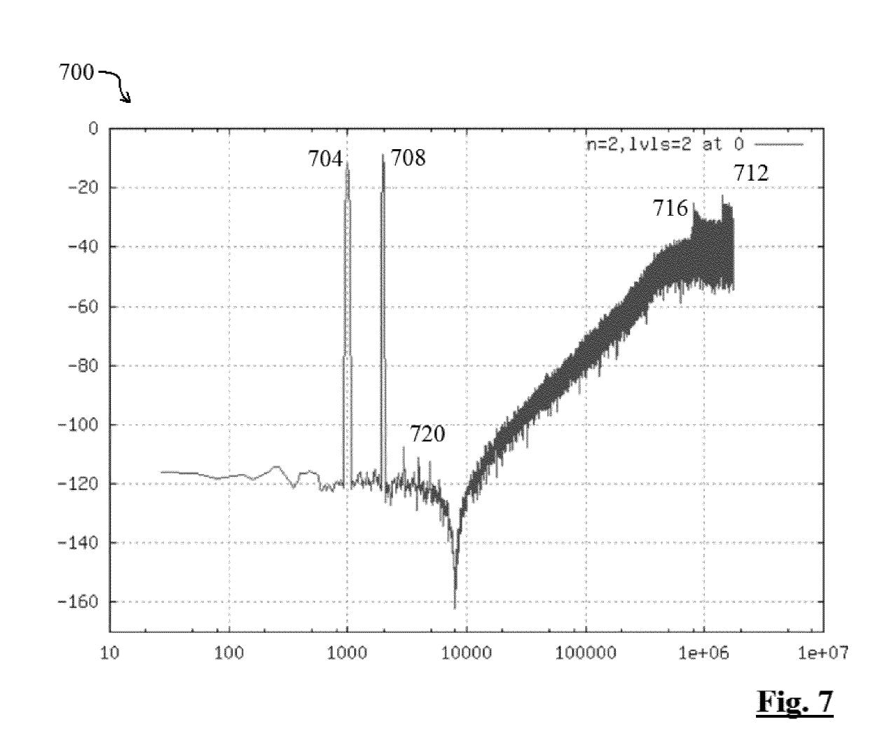

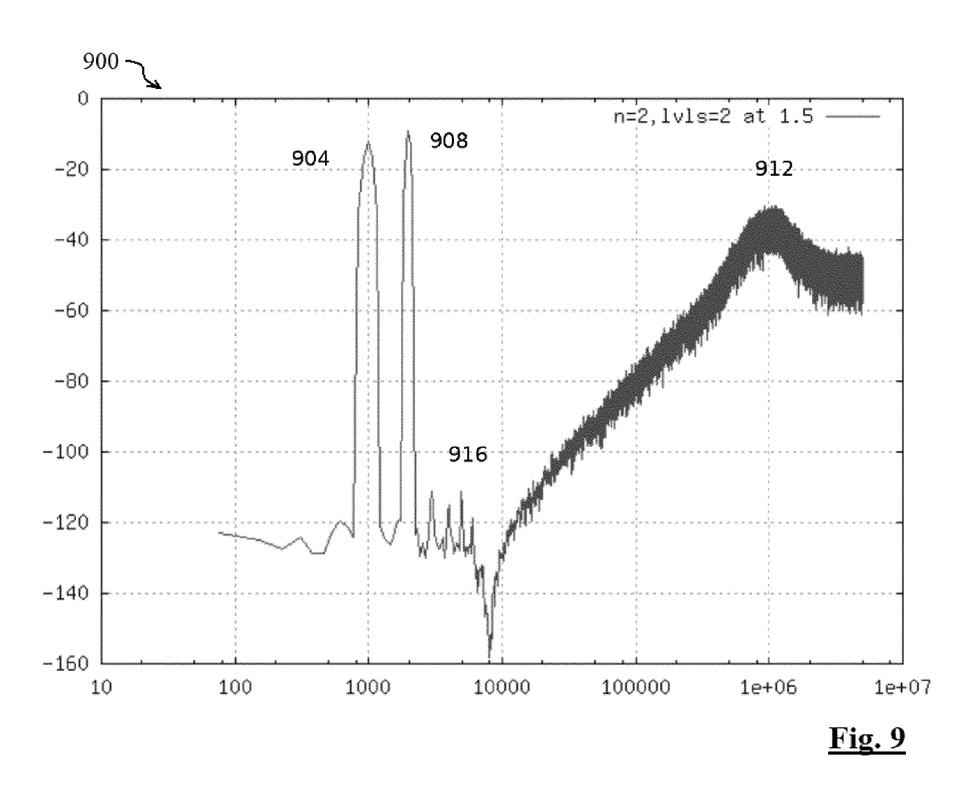

FIG. 7 shows generally at 700 the power spectrum of output waveform 512 of a sigma delta modulator of order two having a two-level quantizer and clocking at 3.5 MHz. This sigma-delta modulator was designed with a noise transfer function having a notch at 8 kHz and was analyzed under the assumption that the output lowpass filter had a very conservative 2 kHz first-order rolloff that would be pre-compensated digitally, and input tones at 1 kHz and 2 kHz were applied, each having peak amplitude ¼ of the full-scale output amplitude.

Under these conditions a signal-to-noise ratio of 92.9 dB is obtained and the average output frequency is 1.08 MHz. It should be noted that this is already almost 20 dB better than the performance of pulse width modulator 300, while switching at a slightly lower frequency. One skilled in the art will recognize that the average switching frequency will vary from 1.08 MHz according to the detailed properties of input signal 108, but cannot exceed one-half of the given 3.5 MHz frequency of clock.

Radio-frequency tones at 712 and generally indicated at 716 are present, but are substantially attenuated relative to corresponding tones 312 and 316 in pulse width modulator 300.

Turning now to the present invention, FIG. 8 shows generally at 800 a novel pulse density modulator (PDM) in accordance with the present invention which is suitable for digital implementation and having the desired properties of high audio accuracy, low electromagnetic interference and practical clock rates. PDM 800 can be seen as a modification of sigma-delta modulator 600 in which the quantizer 608 and register 612 are augmented by the addition of a positive feedback gain 804 and summer 808 to form a hysteretic registered quantizer 812, which serves as a hysteresis element for the modulator. As will be apparent to those of skill in the art, the present invention is not limited to the use of any particular configuration or structure of hysteresis element for the modulator and a variety of other suitable structures will occur to those of skill in the art.

Hysteretic registered quantizer 812 is operable to produce an output switched waveform 816 having hysteresis, that is to say the property of tending to avoid changing state. If the value of feedback gain 804 is zero, then there is no hysteresis and the modulator acts simply as sigma-delta 600. Conversely, if feedback gain 804 is positive then a decision by quantizer 608 at a given cycle is reinforced by positive feedback and therefore more likely to be repeated on the next cycle. There is also negative feedback, through the loops including integrators 604b and 604a, and because this is integral feedback, it will eventually overwhelm the effect of positive feedback 804 and cause pulse-density modulated output 816 to switch, but this may take several cycles—the number depending on the details of coefficients and signal history.

Those skilled in the art will recognize that there are many ways of implementing hysteresis, and that the principle of operation is unaffected by the particular implementation chosen. They will also recognize that some amount of hysteresis is common in practical circuit implementations of quantizers, but is usually regarded as a circuit imperfection leading to reduced performance. They will also know that this effect is a known defect in the design of sigma-delta converters which reduces output switching rate relative to clock rate and therefore reduces quality.

The present invention comprises employing a sigma-delta modulator having substantial hysteresis and increasing the clock rate to the sigma-delta modulator to compensate for the loss of quality introduced by the hysteresis. A skilled technician might expect these two effects to simply cancel, but the present inventor has determined that, unexpectedly, this is not in fact the case because for a given average output switching rate the fast hysteretic loop has a finer timing resolution than the slow non-hysteretic loop.

FIG. 9 shows generally at 900 the power spectrum of pulse-density modulated output 816 of pulse density modulator 800 when clocked at 10 MHz and with a positive feedback coefficient 812 having a value of 1.5 and having the same input tones as for the modulators with power spectra 300 and 700, the tones being visible as spikes 904 and 908. Under these conditions, modulated output 816 switches at an average frequency of 1.04 MHz and in-band distortion 916 is measured at −100.6 dBA relative to input signal 108. This is superior to the performance of sigma-delta modulator output spectrum 700 both as to switching rate (slightly less at 1.04 MHz vs. 1.08 MHz) and signal-to-noise ratio (substantially better at 100.6 dB vs. 92.9).

This demonstrates that by adding hysteresis and compensating for reduced switching with increased clock rate, a modulator having the same average output rate as that of a conventional sigma-delta modulator but with substantially improved signal-to-noise ratio can be obtained. Because the average switching rates are the same, switching efficiency is (to a good approximation) the same.

As can be seen, radio-frequency noise tones 912 are well dithered, having peak values similar to those of conventional sigma-delta modulators and not exhibiting signal-dependent peaks like those seen at 712.

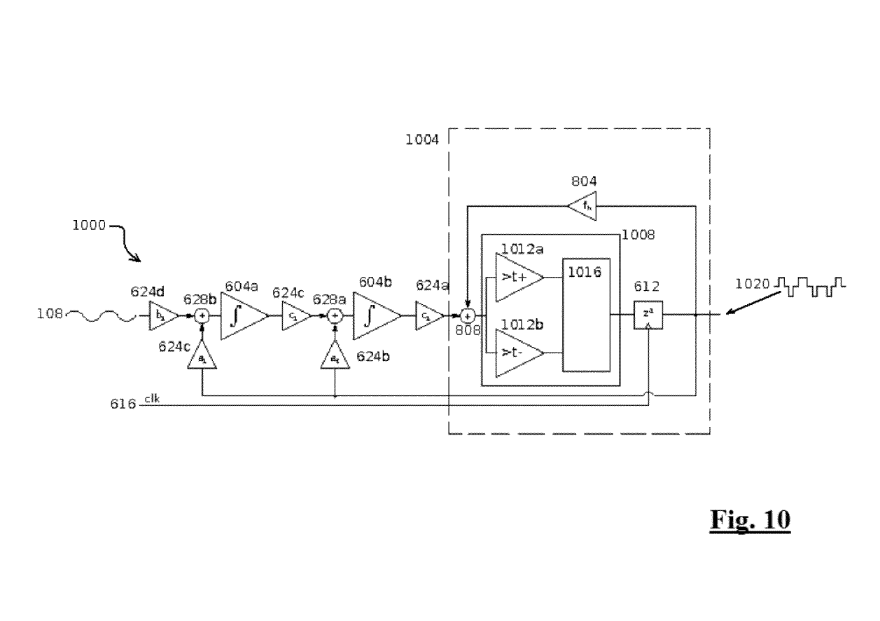

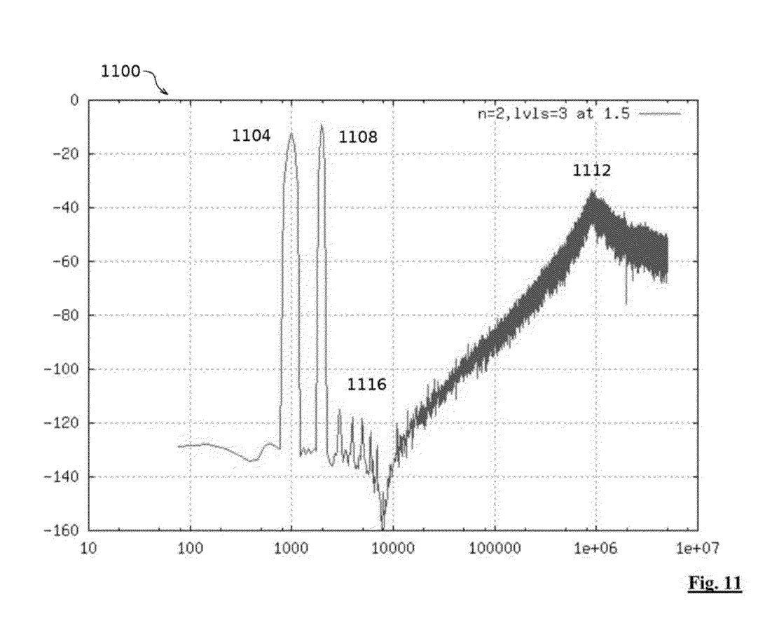

FIG. 10 shows generally at 1000 a Class BD embodiment of a pulse density modulator in accordance with the present invention. It can be seen as a variation of pulse density modulator 800 in which two-level registered quantizer 812 is replaced by a three-level hysteretic registered quantizer, shown generally at 1004, which is another suitable hysteresis element. Three-level registered quantizer 1004 comprises a three-level quantizer, indicated generally at 1008, which is operable to define a next state for register 612, with register 612 changing its state according to clock signal 616 and operable through a positive feedback gain 804 and summer 808 to contribute to the input of three-level quantizer 1004.

Three-level quantizer 1008 comprises a pair of digital comparators 1012a and 1012b, each operable to compare the output of summer 808 with a reference value (labeled as “t+” and “t−” respectively) and an encoder 1016 operable to encode the ensemble of output states of comparators 1012a and 1012b as a decision from the set {−1, 0, 1}. An example of a sequence of such decisions is indicated at 1020.

Changing the extent of hysteresis trades off signal to noise ratio (a measure of quality) against switching rate (a cause of power dissipation). The extent of hysteresis in Class BD hysteretic modulator 1000 can be adjusted by changing the value of positive feedback coefficient 804, together with threshold values “t+” and “t−” of comparators 1012a and 1012b. If it is desired to increase the average widths of the “+1” and “−1” states, then positive feedback coefficient 804 should be increased. In addition, if it is desired to increase the average widths of “0” states then “t+” can be increased and “t−” decreased.

The values of positive feedback coefficient and thresholds “t+” and “t−” can be fixed at the time of design or can be set during operation. These parameters could also be selected by a user choice, as for example in headphone systems where a user chooses “heavy metal” (large hysteresis and high thresholds) or “classical” modes (reduced hysteresis). Hysteresis parameters can also be responsive to power availability: for example choosing low hysteresis levels when batteries are charging or freshly charged and higher hysteresis levels when batteries are in poor condition. Hysteresis parameters can also be responsive to statistical properties of the signal being reproduced: for example reducing hysteresis during quiet passages and increasing it for loud passages. Combinations of these parameter adjustment strategies can also be desirable, for example reducing hysteresis while batteries are charging or fresh but making it increasingly responsive to signal statistics as batteries drain.

FIG. 11 shows generally at 1100 the power spectrum at output 1020 of an embodiment of Class BD hysteretic modulator 1000 in which input signal 108 comprises sinusoidal tones at 1 kHz and 2 kHz, each at a peak amplitude of ¼; in which clock 616 operates at 10 MHz; positive feedback coefficient 804 has the value 1.5; and in which coefficients “t+” and “t−” of comparators 1012a and 1012b are set to 5 and −5 respectively. Under these conditions the average rate of transitions at output 1020 is 1.19 MHz and an A-weighted signal-to-noise of 106.2 dB is obtained. This is approximately 6 dB better than for the 2-level case with power spectrum 900, and the peak radio-frequency power 1112 is also somewhat better than for power spectrum 900.

A further advantage of Class BD hysteretic modulator 1000 over Class AD modulator 800 is that most transitions are smaller: between 0 and +1 or 0 and −1, where in Class AD modulator 800 all transitions are between +1 and −1. It is known that switching losses are proportional to the square of the change in voltage in transitions, and Class BD modulator 1000 accordingly has losses almost four times smaller than those of Class AD modulator 800.

The present invention provides a novel pulse density modulator which includes at least one sigma delta modulator which operates at a clock rate selected to provide a pre-selected timing resolution for sampling an input signal and which employs a hysteresis element to reduce the average transition rate of the output signal of the sigma delta modulator to reduce switching losses. The novel pulse density modulator can provide at least a two or three level output, as desired.

The above-described embodiments of the invention are intended to be examples of the present invention and alterations and modifications may be effected thereto, by those of skill in the art, without departing from the scope of the invention which is defined solely by the claims appended hereto.

We claim:

1. A hysteretic pulse-density modulator operating on an input signal to produce an output signal, comprising:
at least one a sigma delta modulator operating at a clock rate selected to provide a predefined level of timing resolution for sampling the input signal, the sigma delta modulator including a hysteresis element operable to reduce the average transition rate of the output signal of the sigma delta modulator to reduce switching losses.

2. The hysteretic pulse-density modulator of claim 1 wherein the sigma delta modulator is of order two and wherein the output signal is a two level output.

3. The hysteretic pulse-density modulator of claim 1 wherein the sigma delta modulator is of order two and wherein the output signal is a three level output.

4. The hysteretic pulse-density modulator of claim 1 wherein the hysteresis element comprises a hysteretic registered quantizer.

5. The hysteretic pulse-density modulator of claim 3 wherein the hysteresis element comprises a three-level hysteretic registered quantizer.
